(19) United States
(12) Patent Application Publication
(10) Pub. No.: US 2022/0367545 A1
(43) Pub. Date: Nov. 17, 2022

(54) SEMICONDUCTOR DEVICE AND IMAGING DEVICE

(71) Applicant: SONY SEMICONDUCTOR SOLUTIONS CORPORATION, KANAGAWA (JP)

(72) Inventor: NAOHIKO KIMIZUKA, KANAGAWA (JP)

(21) Appl. No.: 17/623,848

(22) PCT Filed: May 26, 2020
(86) PCT No.: PCT/JP2020/020667

§ 371 Date: Dec. 29, 2021

(30) Foreign Application Priority Data
Jul. 12, 2019 (JP) 2019-129745

(51) Int. Cl. H01L 27/146

(52) U.S. Cl. CPC H01L 27/14614; H01L 27/14643; H01L 27/14689

(57) ABSTRACT

Provided are a semiconductor device capable of reducing a substrate bias effect, and an imaging device using the semiconductor device. The semiconductor device includes a semiconductor substrate, and a field effect transistor provided on a first main surface of the semiconductor substrate. The field effect transistor includes a semiconductor region in which a channel is formed, a gate electrode covering the semiconductor region, a gate insulating film disposed between the semiconductor region and the gate electrode, and a first insulating film disposed between the semiconductor region and the semiconductor substrate. The semiconductor region has an upper surface, a first side surface located on one side of the upper surface in a first direction parallel to the upper surface, and a second side surface located on the other side of the upper surface in the first direction. The gate electrode has a first portion facing the upper surface with the gate insulating film interposed therebetween, a second portion facing the first side surface with the gate insulating film interposed therebetween, and a third portion facing the second side surface with the gate insulating film interposed therebetween.

### TECHNICAL FIELD

The present disclosure relates to a semiconductor device and an imaging device.

### BACKGROUND ART

As a semiconductor device used for a complementary metal oxide semiconductor (CMOS) image sensor, a non-planar transistor having a vertical gate electrode and a channel is known (for example, see Patent Document 1).

### CITATION LIST

### Patent Document

Patent Document 1: Japanese Patent Application Laid-Open No. 2006-121093

### SUMMARY OF THE INVENTION

### Problems to be Solved by the Invention

The non-planar transistor disclosed in Patent Document 1 receives a substrate bias effect because its channel region is in contact with a semiconductor substrate.

The present disclosure has been made in view of such circumstances, and an object thereof is to provide a semiconductor device capable of reducing a substrate bias effect and an imaging device using the semiconductor device.

### Solutions to Problems

A semiconductor device according to one aspect of the present disclosure includes: a semiconductor substrate; and a field effect transistor provided on a first main surface of the semiconductor substrate, in which the field effect transistor includes a semiconductor region in which a channel is formed, a gate electrode covering the semiconductor region, a gate insulating film disposed between the semiconductor region and the gate electrode, and a first insulating film disposed between the semiconductor region and the semiconductor substrate, the semiconductor region has an upper surface, a first side surface located on one side of the upper surface in a first direction parallel to the upper surface, and a second side surface located on the other side of the upper surface in the first direction, and the gate electrode has a first portion facing the upper surface with the gate insulating film interposed therebetween, a second portion facing the first side surface with the gate insulating film interposed therebetween, and a third portion facing the second side surface with the gate insulating film interposed therebetween.

As a result, the semiconductor region and the semiconductor substrate are insulated from each other by the first insulating film. Therefore, the semiconductor device can reduce the substrate bias effect.

An imaging device according to one aspect of the present disclosure includes: a light receiving element; and a semiconductor device configured to transmit an electric signal photoelectrically converted by the light receiving element, in which the semiconductor device includes a semiconductor substrate, and a field effect transistor provided on the semiconductor substrate, the field effect transistor includes a semiconductor region in which a channel is formed, a gate electrode covering the semiconductor region, a gate insulating film disposed between the semiconductor region and the gate electrode, and a first insulating film disposed between the semiconductor region and the semiconductor substrate, the semiconductor region has an upper surface, a first side surface located on one side of the upper surface in a first direction parallel to the upper surface, and a second side surface located on the other side of the upper surface in the first direction, and the gate electrode has a first portion facing the upper surface with the gate insulating film interposed therebetween, a second portion facing the first side surface with the gate insulating film interposed therebetween, and a third portion facing the second side surface with the gate insulating film interposed therebetween.

As a result, the imaging device can use the semiconductor device having a reduced substrate bias effect as a semiconductor device for transmitting an electric signal photoelectrically converted by the light receiving element. Therefore, the performance of the imaging device can be improved.

### BRIEF DESCRIPTION OF DRAWINGS

FIG. 1 is a plan view illustrating a configuration example of a semiconductor device according to a first embodiment of the present disclosure.

FIG. 2 is a cross-sectional view illustrating the configuration example of the semiconductor device according to the first embodiment of the present disclosure.

FIG. 3 is a cross-sectional view illustrating the configuration example of the semiconductor device according to the first embodiment of the present disclosure.

FIG. 4 is a cross-sectional view illustrating the configuration example of the semiconductor device according to the first embodiment of the present disclosure.

FIG. 5 is a plan view illustrating the semiconductor device according to the first embodiment of the present disclosure except a gate electrode.

FIG. 6A is a cross-sectional view illustrating a method for manufacturing the semiconductor device according to the first embodiment of the present disclosure.

FIG. 6B is a cross-sectional view illustrating the method for manufacturing the semiconductor device according to the first embodiment of the present disclosure.

FIG. 7A is a cross-sectional view illustrating the method for manufacturing the semiconductor device according to the first embodiment of the present disclosure.

FIG. 7B is a cross-sectional view illustrating the method for manufacturing the semiconductor device according to the first embodiment of the present disclosure.

FIG. 8A is a cross-sectional view illustrating the method for manufacturing the semiconductor device according to the first embodiment of the present disclosure.

FIG. 8B is a cross-sectional view illustrating the method for manufacturing the semiconductor device according to the first embodiment of the present disclosure.

FIG. 9A is a cross-sectional view illustrating the method for manufacturing the semiconductor device according to the first embodiment of the present disclosure.

FIG. 9B is a cross-sectional view illustrating the method for manufacturing the semiconductor device according to the first embodiment of the present disclosure.

FIG. 10A a cross-sectional view illustrating the method for manufacturing the semiconductor device according to the first embodiment of the present disclosure.

FIG. 10B is a cross-sectional view illustrating the method for manufacturing the semiconductor device according to the first embodiment of the present disclosure.

FIG. 11A is a cross-sectional view illustrating the method for manufacturing the semiconductor device according to the first embodiment of the present disclosure.

FIG. 11B is a cross-sectional view illustrating the method for manufacturing the semiconductor device according to the first embodiment of the present disclosure.

FIG. 12A is a cross-sectional view illustrating the method for manufacturing the semiconductor device according to the first embodiment of the present disclosure.

FIG. 12B is a cross-sectional view illustrating the method for manufacturing the semiconductor device according to the first embodiment of the present disclosure.

FIG. 13A is a cross-sectional view illustrating the method for manufacturing the semiconductor device according to the first embodiment of the present disclosure.

FIG. 13B is a cross-sectional view illustrating the method for manufacturing the semiconductor device according to the first embodiment of the present disclosure.

FIG. 14A is a cross-sectional view illustrating the method for manufacturing the semiconductor device according to the first embodiment of the present disclosure.

FIG. 14B is a cross-sectional view illustrating the method for manufacturing the semiconductor device according to the first embodiment of the present disclosure.

FIG. 15A is a cross-sectional view illustrating the method for manufacturing the semiconductor device according to the first embodiment of the present disclosure.

FIG. 15B is a cross-sectional view illustrating the method for manufacturing the semiconductor device according to the first embodiment of the present disclosure.

FIG. 16A is a cross-sectional view illustrating the method for manufacturing the semiconductor device according to the first embodiment of the present disclosure.

FIG. 16B is a cross-sectional view illustrating the method for manufacturing the semiconductor device according to the first embodiment of the present disclosure.

FIG. 17 is a cross-sectional view illustrating a configuration example of a semiconductor device according to a second embodiment of the present disclosure.

FIG. 18 is a cross-sectional view illustrating the configuration example of the semiconductor device according to the second embodiment of the present disclosure.

FIG. 19A is a cross-sectional view illustrating a method for manufacturing the semiconductor device according to the second embodiment of the present disclosure.

FIG. 19B is a cross-sectional view illustrating the method for manufacturing the semiconductor device according to the second embodiment of the present disclosure.

FIG. 20A is a cross-sectional view illustrating the method for manufacturing the semiconductor device according to the second embodiment of the present disclosure.

FIG. 20B is a cross-sectional view illustrating the method for manufacturing the semiconductor device according to the second embodiment of the present disclosure.

FIG. 21A is a cross-sectional view illustrating the method for manufacturing the semiconductor device according to the second embodiment of the present disclosure.

FIG. 21B is a cross-sectional view illustrating the method for manufacturing the semiconductor device according to the second embodiment of the present disclosure.

FIG. 22 is a schematic diagram illustrating a configuration example of an imaging device according to a third embodiment of the present disclosure.

FIG. 23 is a circuit diagram illustrating a configuration example of a pixel unit according to the third embodiment of the present disclosure.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs. However, it should be noted that the drawings are schematic, and relations between thicknesses and plane dimensions, ratios between thicknesses of respective layers, and the like differ from the actual ones. Therefore, specific thicknesses and dimensions should be determined in consideration of the following description. Furthermore, it is needless to say that some portions are different in dimensional relationship and ratio between the drawings.

In the following description, definitions of directions, such as upper and lower sides, are merely definitions for convenience of explanation, and do not limit the technical idea of the present disclosure. For example, it is needless to say that if an object is observed in a 90 degree-rotated state, the upper and lower sides are read as being converted into left and right sides, and if the object is observed in a 180 degree-rotated state, the upper and lower sides are read as being inverted.

In the following description, directions may be described using words “X-axis direction”, “Y-axis direction”, and “Z-axis direction”. For example, the X-axis direction and the Y-axis direction are directions parallel to an upper surface 10a of a semiconductor region 10. The X-axis direction and the Y-axis direction are also referred to as horizontal directions. The Z-axis direction is a direction perpendicular to the upper surface 10a of the semiconductor region 10. The Z-axis direction is also referred to as a depth direction. The X-axis direction, the Y-axis direction, and the Z-axis direction are orthogonal to each other. Note that the X-axis direction is an example of a “second direction” in the present disclosure, the Y-axis direction is an example of a “first direction” in the present disclosure, and the Z-axis direction is an example of a “third direction” in the present disclosure.

In the following description, it will be exemplified that a first conductivity type is an N type and a second conductivity type is a P type. However, the conductivity type may be selected in the opposite relationship, and the first conductivity type may be the P type and the second conductivity type may be the N type.

### First Embodiment

(Configuration Example of Semiconductor Device)

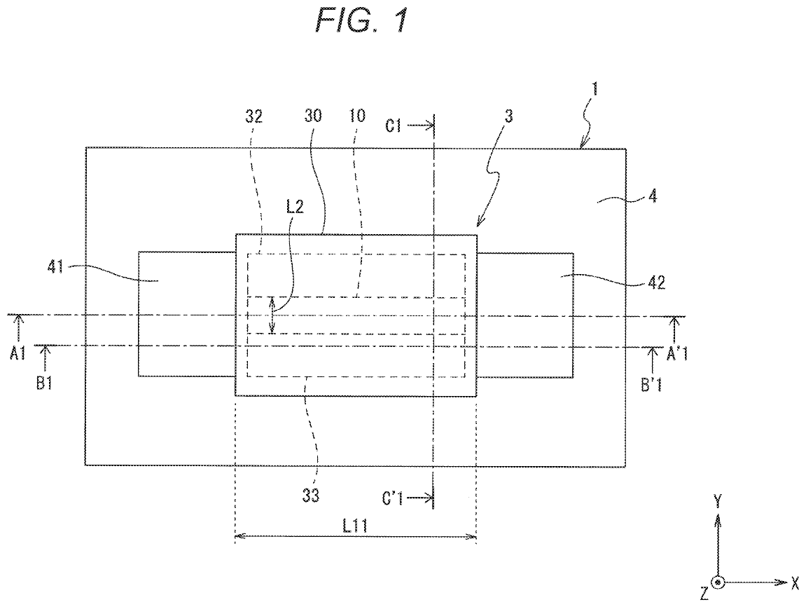

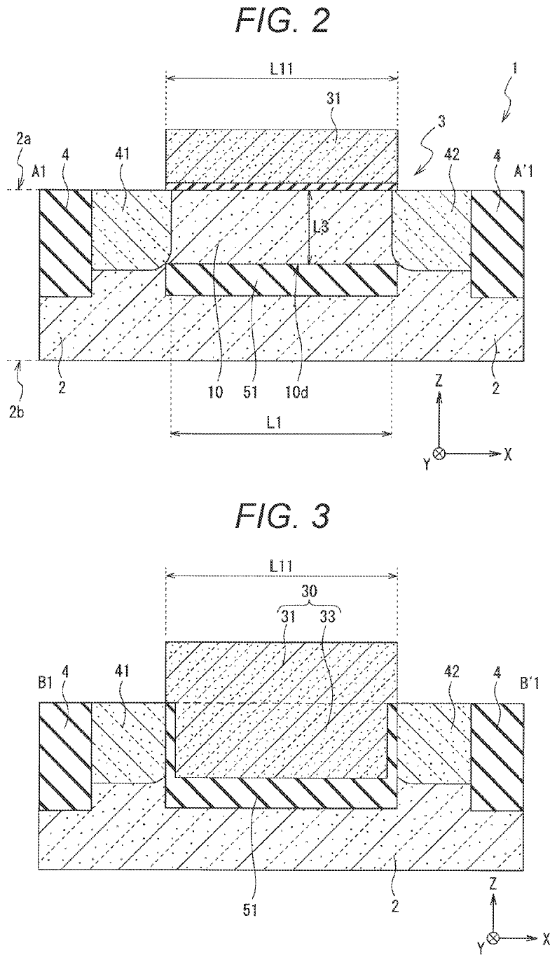

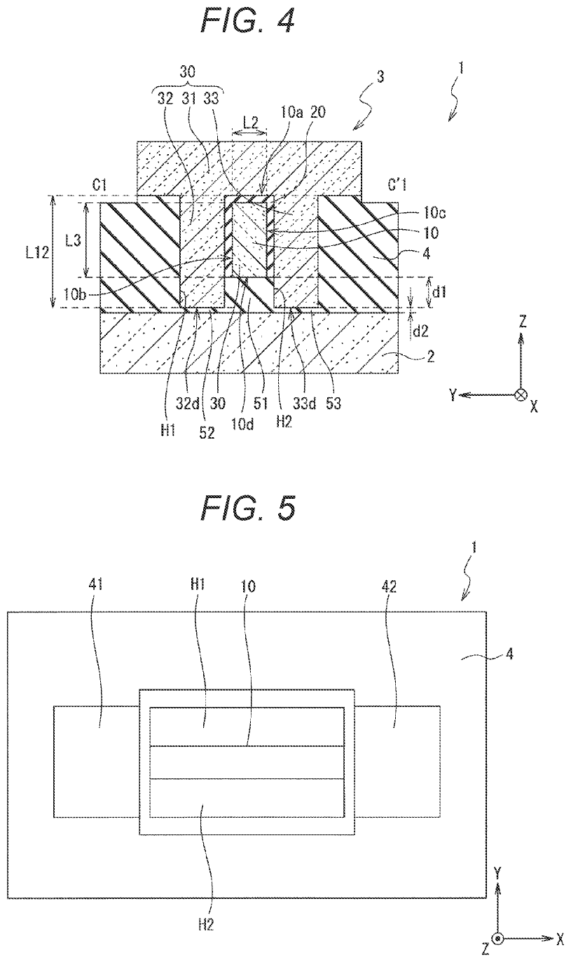

FIG. 1 is a plan view illustrating a configuration example of a semiconductor device 1 according to a first embodiment of the present disclosure. FIGS. 2 to 4 are cross-sectional views illustrating the configuration example of the semiconductor device 1 according to the first embodiment of the present disclosure. FIG. 2 illustrates a cross section taken along line A1-A′1 of the plan view illustrated in FIG. 1. FIG. 3 illustrates a cross section taken along line B1-B′1 of the plan view illustrated in FIG. 1. FIG. 4 illustrates a cross section taken along line C1-C′1 of the plan view illustrated in FIG. 1. FIG. 5 is a plan view illustrating the semiconductor device 1 according to the first embodiment of the present disclosure except a gate electrode 30.

As illustrated in FIGS. 1 to 5, the semiconductor device 1 according to the first embodiment includes a semiconductor substrate 2, a metal oxide semiconductor (MOS) transistor 3 in the first conductivity type (an example of a “field effect transistor” in the present disclosure) provided on the semiconductor substrate 2, and an element isolation layer 4 provided on the semiconductor substrate 2.

The semiconductor substrate 2 includes, for example, single crystal silicon. The semiconductor substrate 2 has a front surface 2a (an example of a “first main surface” in the present disclosure) and a back surface 2b located on the opposite side of the front surface 2a. The MOS transistor 3 is provided on the front surface 2a of the semiconductor substrate 2. The element isolation layer 4 is an insulating film for electrically isolating neighboring elements in the horizontal direction from to each other, and is formed as, for example, a silicon oxide film (SiO₂ film).

The MOS transistor 3 includes a semiconductor region 10 in the second conductivity type (e.g., P type) in which a channel is formed, a gate insulating film 20, a gate electrode 30, a source region 41 and a drain region 42 provided on the semiconductor substrate 2, a first insulating film 51, a second insulating film 52, and a third insulating film 53.

The semiconductor region 10 is a part of the semiconductor substrate 2, and includes, for example, single crystal silicon. The semiconductor region 10 is a portion formed by etching the part of the semiconductor substrate 2 on the front surface 2a side. The shape of the semiconductor region 10 is, for example, a fin shape.

The semiconductor region 10 has a shape to be long in the X-axis direction and short in the Y-axis direction. For example, a length L1 of the semiconductor region 10 in the X-axis direction is 150 nm or more and 700 nm or less. A length (width) L2 of the semiconductor region 10 in the Y-axis direction is 15 nm or more and 1000 nm or less. A length (depth) L3 of the semiconductor region 10 in the Z-axis direction is 100 nm or more and 1000 nm or less.

A trench H1 having the second insulating film 52 as its bottom surface is provided on one side of the semiconductor region 10 in the Y-axis direction, and a trench H2 having the third insulating film 53 as its bottom surface is provided on the other side of the semiconductor region 10 in the Y-axis direction. A second portion 32 of the gate electrode 30 is disposed in the trench H1. A third portion 33 of the gate electrode 30 is disposed in the trench H2. The second portion 32 and the third portion 33 will be described later. The semiconductor region 10 is sandwiched between the second portion 32 disposed in the trench H1 and the third portion 33 disposed in the trench H2 in the Y-axis direction.

The gate insulating film 20 is provided to cover an upper surface 10a, a first side surface 10b, and a second side surface 10c of the semiconductor region 10. The first side surface 10b is located on one side of the upper surface 10a in the Y-axis direction. The second side surface 10c is located on the other side of the upper surface 10a in the Y axis direction. The gate insulating film 20 includes, for example, an SiO₂ film.

The gate electrode 30 covers the semiconductor region 10 with the gate insulating film 20 interposed therebetween. For example, the gate electrode 30 has a first portion 31 facing the upper surface 10a of the semiconductor region 10 with the gate insulating film 20 interposed therebetween, a second portion 32 facing the first side surface 10b of the semiconductor region 10 with the gate insulating film 20 interposed therebetween, and a third portion 33 facing the second side surface 10c of the semiconductor region 10 with the gate insulating film 20 interposed therebetween. Each of the second portion 32 and the third portion 33 are connected to a lower surface of the first portion 31.

Therefore, the gate electrode 30 can simultaneously apply a gate voltage to the upper surface 10a, the first side surface 10b, and the second side surface 10c of the semiconductor region 10. That is, the gate electrode 30 can simultaneously apply a gate voltage to the semiconductor region 10 from a total of three directions including the upper side and the left and right sides. Therefore, the gate electrode 30 can completely deplete the semiconductor region 10.

A length L11 of the first portion 31 in the X-axis direction is, for example, 300 nm or more and 500 nm or less. A length L12 of each of the second portion 32 and the third portion 33 in the Z-axis direction is, for example, 120 nm or more and 1200 nm or less. The gate electrode 30 is formed as, for example, a polysilicon (Poly-Si) film.

The source region 41 is provided on the front surface 2a of the semiconductor substrate 2 and in the vicinity thereof. The source region 41 is connected to one side of the semiconductor region 10. The drain region 42 is provided on the front surface 2a of the semiconductor substrate 2 and in the vicinity thereof. The drain region 42 is connected to the other side of the semiconductor region 10 in the X-axis direction. The source region 41 and the drain region 42 are in the first conductivity type (e.g., N type).

The first insulating film 51 is disposed between a lower surface 10d of the semiconductor region 10 and the semiconductor substrate 2. The second insulating film 52 is disposed between a lower surface 32d of the second portion 32 of the gate electrode 30 and the semiconductor substrate 2. The third insulating film 53 is disposed between a lower surface 33d of the third portion 33 of the gate electrode 30 and the semiconductor substrate 2. The second insulating film 52 and the third insulating film 53 are thinner than the first insulating film 51. A thickness d1 of the first insulating film 51 is 10 nm or more and 800 nm or less. A thickness d2 of each of the second insulating film 52 and the third insulating film 53 is 1 nm or more and 20 nm or less. The first insulating film 51, the second insulating film 52, and the third insulating film 53 are formed as, for example, SiO₂ films.

The MOS transistor 3 according to the embodiments of the present disclosure may be referred to as a MOS transistor having a dug gate structure based on the shape in which the second portion 32 and the third portion 33 of the gate electrode 30 are disposed in the trenches H1 and H2. Alternatively, since the semiconductor region 10 has a fin shape, the MOS transistor 3 may be referred to as a fin field effect transistor (FinFET). Alternatively, the MOS transistor may be called a dug FinFET from the aforementioned two shapes.

(Method for Manufacturing Semiconductor Device)

Next, a method for manufacturing the semiconductor device 1 according to the first embodiment of the present disclosure will be described. In this example, as a method for manufacturing the semiconductor device 1, a method of forming the MOS transistor 3 having the dug gate structure as illustrated in FIGS. 1 to 5 together with a MOS transistor having a planar gate electrode in a planar gate structure on the same semiconductor substrate 2 will be described.

Note that the semiconductor device 1 is manufactured using various apparatuses such as a film forming apparatus (including a chemical vapor deposition (CVD) apparatus or a sputtering apparatus), an ion implantation apparatus, a heat treatment apparatus, an etching apparatus, and a chemical mechanical polishing (CMP) apparatus. Hereinafter, these apparatuses will be collectively referred to as a manufacturing apparatus.

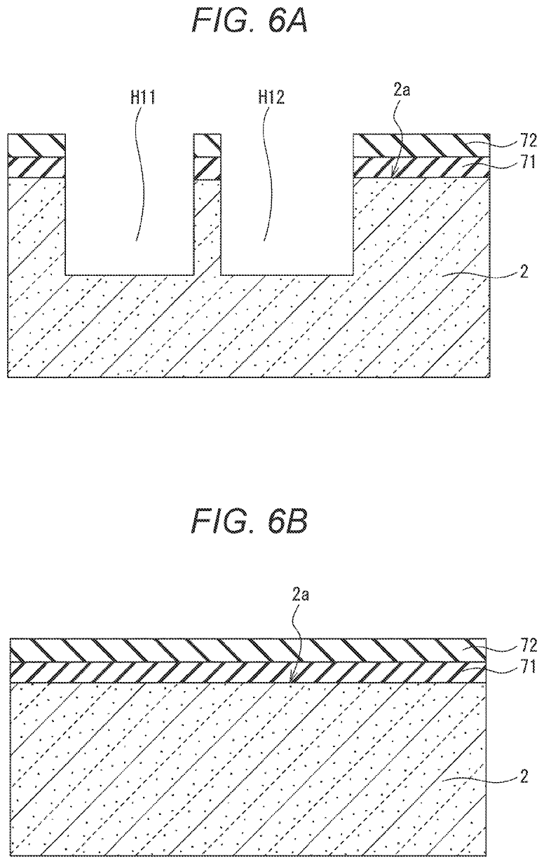

FIGS. 6A to 16B are cross-sectional views illustrating the method for manufacturing the semiconductor device 1 according to the first embodiment of the present disclosure in processing order. In FIGS. 6A to 16B, A of each drawing illustrates a region where the MOS transistor 3 having the dug gate structure is formed (hereinafter, referred to as the dug region), and B of each drawing illustrates a region where the MOS transistor having the planar gate structure is formed (hereinafter, referred to as the planar region).

In FIGS. 6A and 6B, the manufacturing apparatus forms a silicon nitride film (SiN film) 71 on the front surface 2a of the semiconductor substrate 2 using a CVD method. Next, the manufacturing apparatus forms an SiO₂ film 72 on the SiN film 71 using the CVD method. Next, the manufacturing apparatus partially removes the SiO₂ film 72, the SiN film 71, and the semiconductor substrate 2 in the dug region using photolithography and etching techniques. Therefore, the manufacturing apparatus forms trenches H11 and H12 in the dug region.

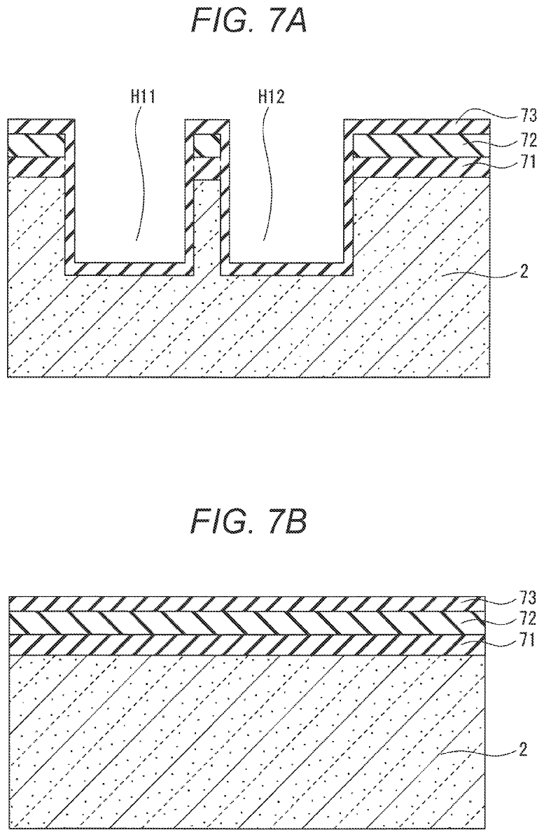

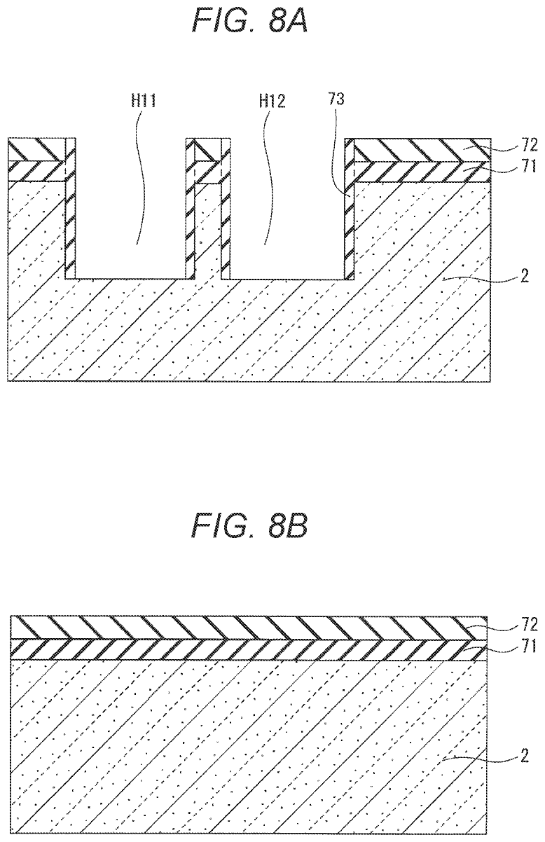

Next, as illustrated in FIGS. 7A and 7B, the manufacturing apparatus forms a SiN film 73 upward of the semiconductor substrate 2 using the CVD method. Next, as illustrated in FIGS. 8A and 8B, the manufacturing apparatus partially removes the SiN film 73 using photolithography and anisotropic etching techniques. In the dug region, the SiN film 73 on bottom surfaces of the trenches H11 and H12 and on the SiO₂ film 72 is removed. Therefore, the semiconductor substrate 2 is exposed from the bottom surfaces of the trenches H11 and H12. Furthermore, the SiN film 73 remains on inner side surfaces of the trenches H11 and H12. Furthermore, in the planar region, the SiN film 73 on the SiO₂ film 72 is removed.

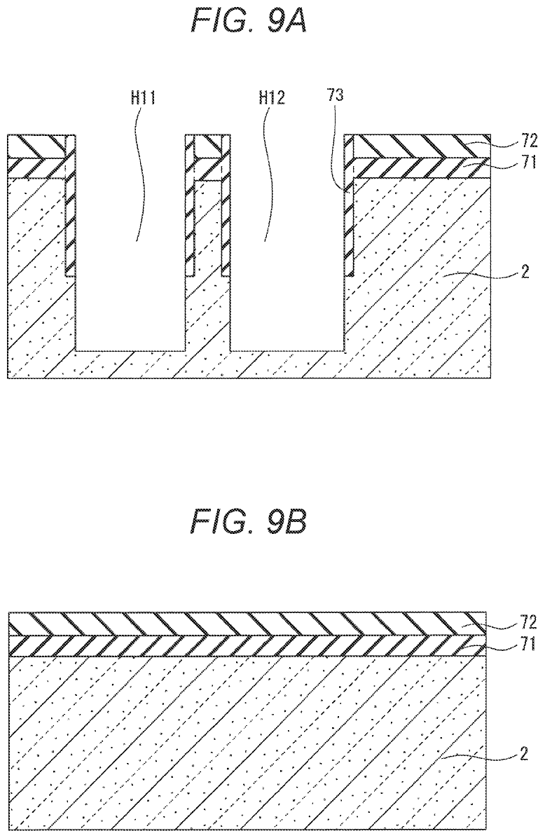

Next, as illustrated in FIGS. 9A and 9B, the manufacturing apparatus etches the bottom surfaces of the trenches H11 and H12 to dig down the trenches H11 and H12. Therefore, the semiconductor substrate 2 is exposed not only from the bottom surfaces of the trenches H11 and H12 but also from lower inner side surfaces of the trenches H11 and H12. This etching is performed by anisotropic etching in order to leave Si below the fin. The manufacturing apparatus digs down the trenches H11 and H12 vertically (i.e., in the depth direction) with respect to the horizontal direction by the anisotropic etching.

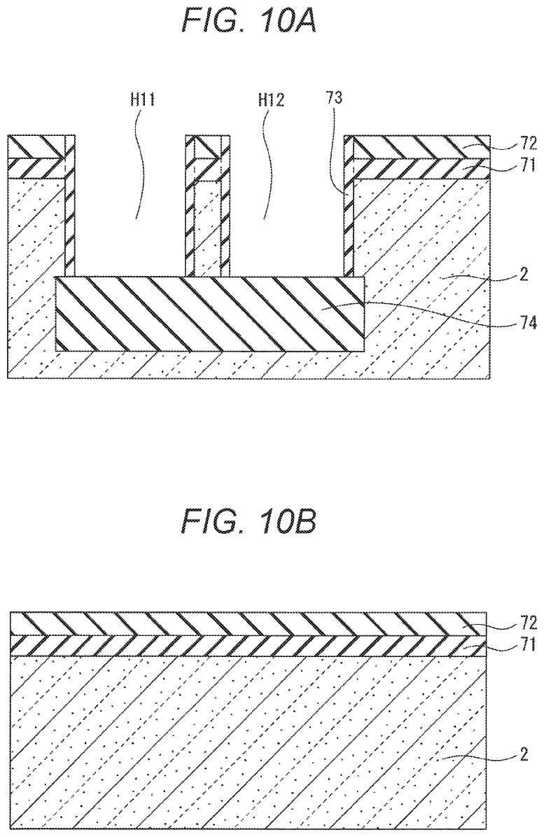

Next, the manufacturing apparatus thermally oxidizes the semiconductor substrate 2. Therefore, as illustrated in FIGS. 10A and 10B, an SiO₂ film 74 is formed in lower portions of the trenches H11 and H12.

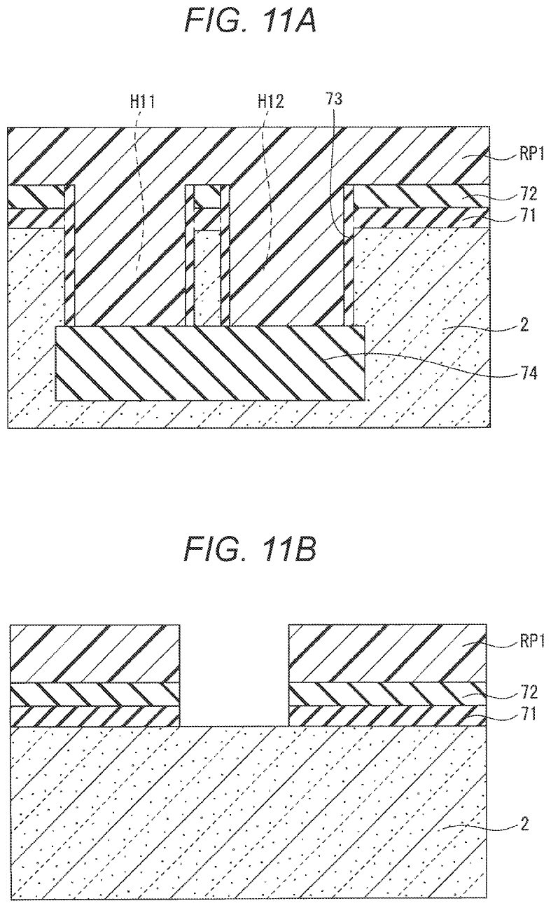

Next, as illustrated in FIGS. 11A and 11B, the manufacturing apparatus forms a resist pattern RP1 in the dug region and the planar region. The resist pattern RP1 has a shape to open a part of the planar region and cover the other regions. Next, the manufacturing apparatus etches and removes the SiO₂ film 72 and the SiN film 71 in the planar region using the resist pattern RP1 as a mask. Therefore, the semiconductor substrate 2 is exposed from below the resist pattern RP1 in the planar region. The SiO₂ film 72 and the SiN film 71 in the dug region remain unetched because they are covered with the resist pattern RP1. Thereafter, the manufacturing apparatus removes the resist pattern RP1.

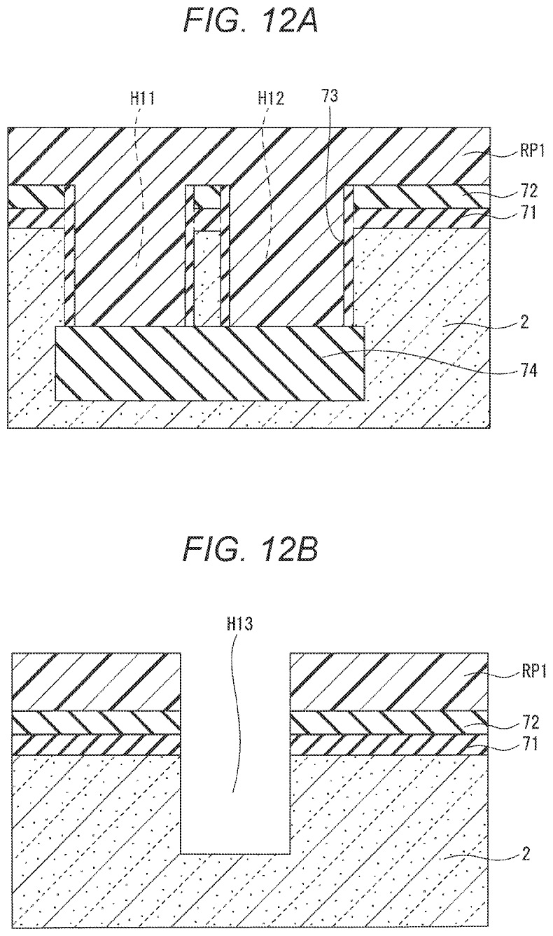

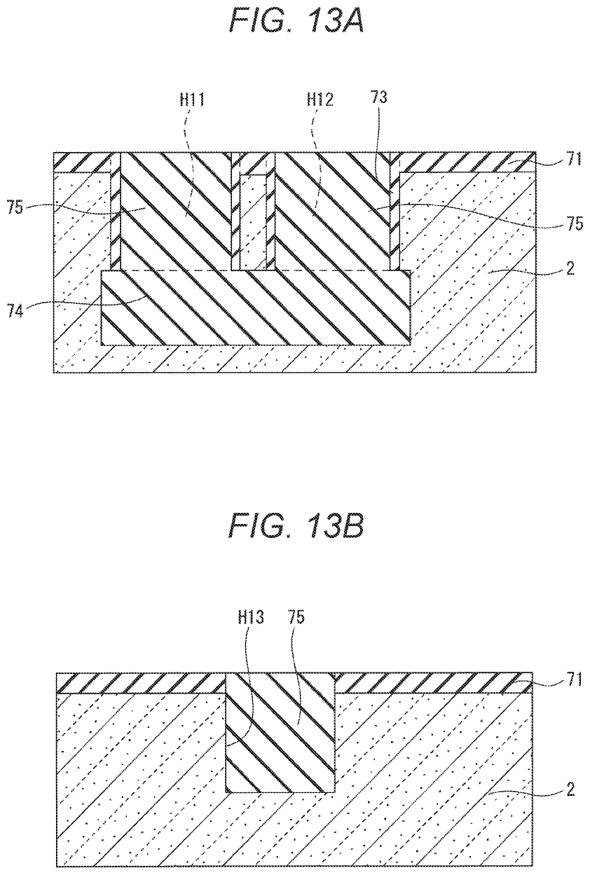

Next, as illustrated in FIGS. 12A and 12B, the manufacturing apparatus etches the semiconductor substrate 2 exposed from below the SiO₂ film 72 in the planar region to form a trench H13 for isolating elements. Thereafter, the manufacturing apparatus removes the resist pattern RP1. Next, the manufacturing apparatus forms an SiO₂ film 75 (see FIGS. 13A and 13B to be described later) upward of the semiconductor substrate 2 to fill the trenches H11, H12, and H13, using the CVD method. Next, the manufacturing apparatus performs CMP processing on the SiO₂ films 75 and 72 to expose the SiN film 71. Therefore, the SiO₂ film 75 remains in the trenches H11, H12, and H13, and the SiO₂ film 75 is removed from the regions other than the trenches H11, H12, and H13. The SiO₂ film 75 remaining in the trench H13 functions as an element isolation layer in the planar region.

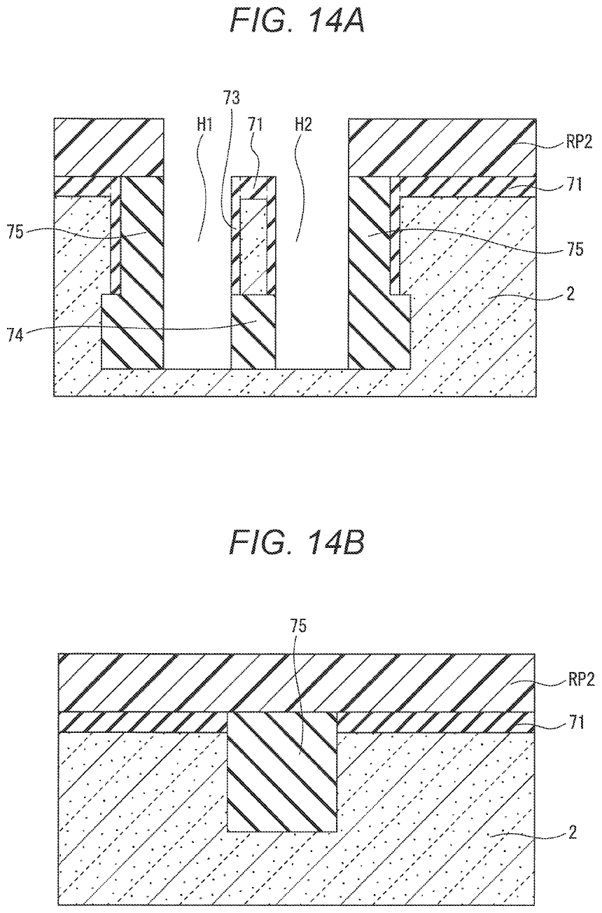

Next, as illustrated in FIGS. 14A and 14B, the manufacturing apparatus forms a resist pattern RP2 in the dug region and the planar region. The resist pattern RP2 has a shape to open partial regions including the trenches H11 and H12 and the vicinity thereof and cover the other regions. Next, the manufacturing apparatus etches and removes the SiO₂ films 75 and 74 in the dug region using the resist pattern RP2 as a mask. Therefore, trenches H1 and H2 are formed in the dug region. The trench H1 is formed inside the trench H11 (see FIG. 13A), and the trench H2 is formed inside the trench H12 (see FIG. 13A). Thereafter, the manufacturing apparatus removes the resist pattern RP2. Note that the SiO₂ film 75 remaining in the trenches H1 and H2 of the dug region functions as an element isolation layer 4 (see FIG. 1) in the dug region.

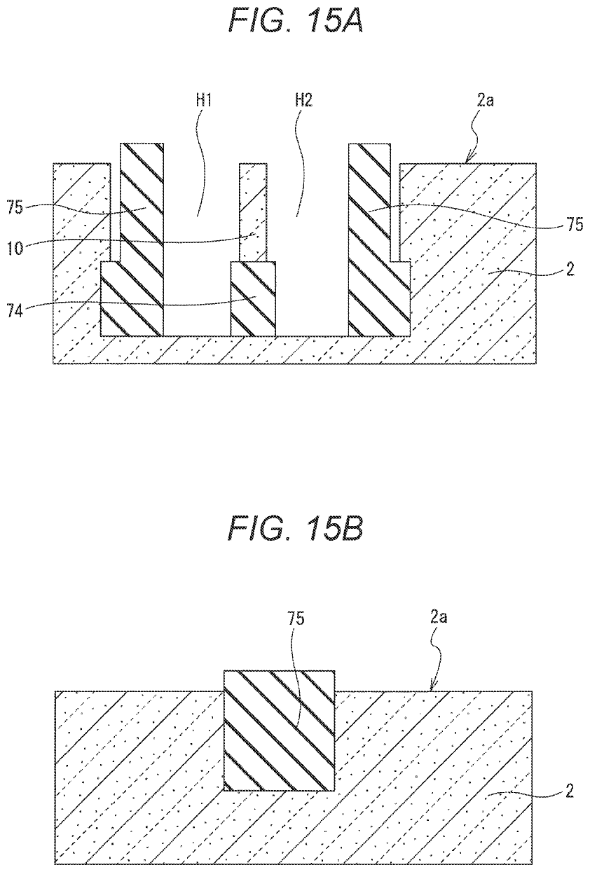

Next, the manufacturing apparatus removes the SiN films 71 and 73 by wet etching. Therefore, as illustrated in FIGS. 15A and 15B, the fin-shaped semiconductor region 10 is exposed in the dug region. Furthermore, the front surface 2a of the semiconductor substrate 2 is exposed both in the dug region and in the planar region.

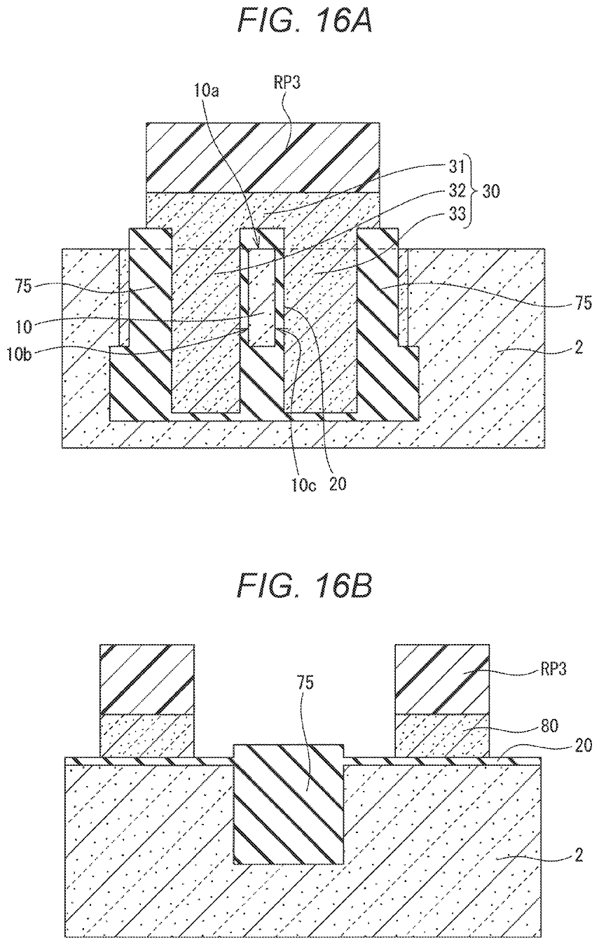

Next, the manufacturing apparatus thermally oxidizes the semiconductor substrate 2 including the semiconductor region 10. Therefore, as illustrated in FIGS. 16A and 16B, the manufacturing apparatus forms a gate insulating film 20 on an upper surface 10a, a first side surface 10b, and a second side surface 10c of the semiconductor region 10 in the dug region, and forms a gate insulating film 20 on the front surface 2a of the semiconductor substrate 2 in the planar region.

Next, the manufacturing apparatus forms a polysilicon film upward of the semiconductor substrate 2 to fill the trenches H1 and H2, using the CVD method. Next, the manufacturing apparatus forms a resist pattern RP3 on the polysilicon film. The resist pattern RP3 has a shape to cover regions where gate electrodes are formed and open the other regions. Next, the manufacturing apparatus etches and removes the polysilicon film using the resist pattern RP3 as a mask. Therefore, the manufacturing apparatus forms a gate electrode 30 in the dug region and forms a gate electrode 80 in the planar region. Thereafter, the manufacturing apparatus removes the resist pattern RP3. Next, the manufacturing apparatus forms a source region and a drain region on the front surface 2a of the semiconductor substrate 2 both in the dug region and in the planar region.

Through the above-described process, the semiconductor device 1 is completed with the MOS transistor 3 having the dug gate structure and the MOS transistor having the planar gate structure on the same semiconductor substrate 2.

As described above, the semiconductor device 1 according to the first embodiment of the present disclosure includes a semiconductor substrate 2 and a MOS transistor 3 in a dug gate structure provided on the semiconductor substrate 2. The MOS transistor 3 includes a semiconductor region 10 in which a channel is formed, a gate electrode 30 covering the semiconductor region 10, a gate insulating film 20 disposed between the semiconductor region 10 and the gate electrode 30, and a first insulating film 51 disposed between the semiconductor region 10 and the semiconductor substrate 2. The semiconductor region 10 has an upper surface 10a, a first side surface 10b, and a second side surface 10c. The first side surface 10b is located on one side of the upper surface 10a in the Y-axis direction parallel to the upper surface 10a. The second side surface 10c is located on the other side of the upper surface 10a in the Y axis direction. The gate electrode 30 has a first portion 31 facing the upper surface 10a of the semiconductor region 10 with the gate insulating film 20 interposed therebetween, a second portion 32 facing the first side surface 10b of the semiconductor region 10 with the gate insulating film 20 interposed therebetween, and a third portion 33 facing the second side surface 10c of the semiconductor region 10 with the gate insulating film 20 interposed therebetween.

As a result, since the semiconductor region 10 and the semiconductor substrate 2 are insulated from each other by the first insulating film 51, a substrate bias effect can be reduced. Furthermore, since the first insulating film 51 is disposed downward of the semiconductor region 10, it is possible to suppress a wraparound of an electric field from the drain region 42 to the source region 41 downward of the semiconductor region 10. Therefore, even in a case where the source region 41 and the drain region 42 are formed deep in the depth direction (Z-axis direction) of the semiconductor substrate 2, it is possible to suppress an occurrence of a short channel effect due to the wraparound of the electric field described above.

Since the source region 41 and the drain region 42 can be formed deep in the Z-axis direction, and furthermore, the substrate bias effect can be reduced, the transconductance (gm) and the gain of the MOS transistor 3 can be increased. Note that, as a method of reducing the substrate bias effect, a silicon on insulator (SOI) substrate may be used, but the SOI substrate is expensive, resulting in an increase in semiconductor device manufacturing cost. According to the first embodiment of the present disclosure, it is not necessary to use an SOI substrate, and thus, it is possible to achieve both the suppression of the increase in manufacturing cost and the reduction of the substrate bias effect.

Furthermore, the gate electrode 30 can simultaneously apply a gate voltage to the semiconductor region 10 from a total of three directions including the upper side and the left and right sides. Therefore, the gate electrode 30 can completely deplete the semiconductor region 10 in an easy manner, thereby reducing an S value indicating a sub-threshold characteristic of the MOS transistor 3. The MOS transistor 3 can perform a switching operation at a high speed.

Furthermore, the second insulating film 52 and the third insulating film 53 are thinner than the first insulating film 51. That is, the lower surface 32d of the second portion 32 and the lower surface 33d of the third portion 33 are located closer to the semiconductor substrate 2 than the lower surface 10d of the semiconductor region 10. Therefore, even in a case where the trenches H1 and H2 are different in depth, it is possible to prevent a difference between a length of a region where the second portion 32 and the first side surface 10b of the semiconductor region 10 face each other in the Z-axis direction and a length of a region where the third portion 33 and the second side surface 10c of the semiconductor region 10 face each other in the Z-axis direction. Therefore, it is possible to suppress a variation in gate width of the gate electrode 30.

### Second Embodiment

In the first embodiment of the present disclosure, it has been described that the gate electrode 30 faces the upper surface 10a, the first side surface 10b, and the second side surface 10c of the semiconductor region 10 with the gate insulating film 20 interposed therebetween. However, in the embodiments of the present disclosure, the positional relationship between the semiconductor region 10 and the gate electrode 30 is not limited thereto. In the embodiments of the present disclosure, in addition to the upper surface 10a, the first side surface 10b, and the second side surface 10c, a lower surface (i.e., a surface on a side closer to the semiconductor substrate 2) 10d of the semiconductor region 10 may also neighbor to the gate electrode 30 with the gate insulating film 20 interposed therebetween. Therefore, the gate width of the MOS transistor having the dug gate structure can be further expanded, and the complete depletion of the semiconductor region 10 can be easier.

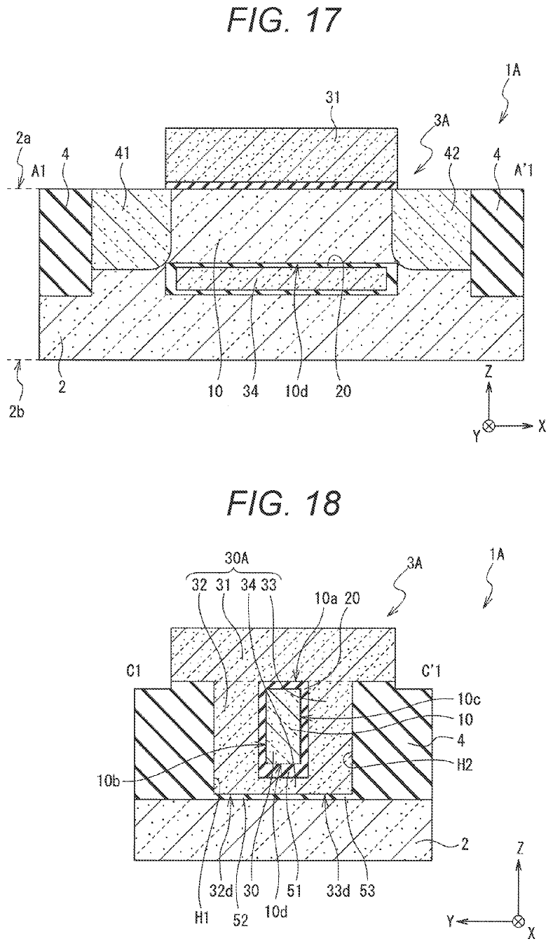

FIGS. 17 and 18 are cross-sectional views illustrating a configuration example of a semiconductor device 1A according to a second embodiment of the present disclosure. FIG. 17 corresponds to the cross section taken along the line A1-A′1 of the plan view illustrated in FIG. 1. FIG. 18 corresponds to the cross section taken along the line C1-C′1 of the plan view illustrated in FIG. 1. As illustrated in FIGS. 17 and 18, the semiconductor device 1A according to the second embodiment includes a MOS transistor 3A in the first conductivity type (an example of a “field effect transistor” in the present disclosure) provided on the semiconductor substrate 2.

Similarly to the MOS transistor 3 according to the first embodiment, the MOS transistor 3A according to the second embodiment is also a MOS transistor having a dug gate structure. In the MOS transistor 3A, a gate electrode 30A is disposed together with the gate insulating film 20 between the lower surface 10d of the semiconductor region 10 and the semiconductor substrate 2. For example, the gate electrode 30A has a first portion 31, a second portion 32, a third portion 33, and a fourth portion 34. The fourth portion 34 neighbors to the lower surface 10d of the semiconductor region 10 with the gate insulating film 20 interposed therebetween.

Therefore, the gate electrode 30A can simultaneously apply a gate voltage to the upper surface 10a, the first side surface 10b, the second side surface 10c, and the lower surface 10d of the semiconductor region 10. That is, the gate electrode 30A can simultaneously apply a gate voltage to the semiconductor region 10 from a total of four directions including the upper and lower sides and the left and right sides.

Next, a method for manufacturing the semiconductor device 1A according to the second embodiment of the present disclosure will be described. In this example, as a method for manufacturing the semiconductor device 1A, a method of forming the MOS transistor 3A having the dug gate structure as illustrated in FIGS. 17 and 18 together with a MOS transistor having a planar gate electrode in a planar gate structure on the same semiconductor substrate 2 will be described.

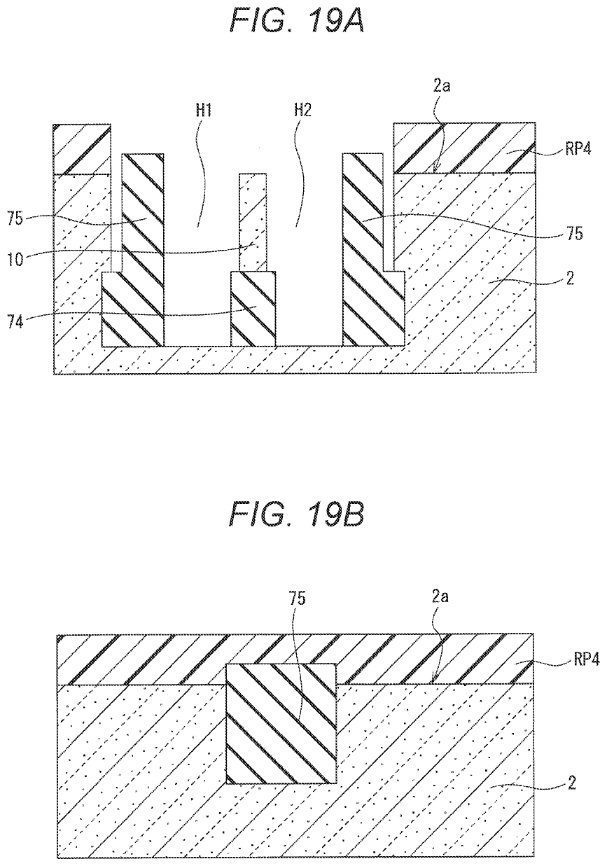

FIGS. 19A to 21B are cross-sectional views illustrating the method for manufacturing the semiconductor device 1A according to the second embodiment of the present disclosure in processing order. In FIGS. 19A to 21B, A of each drawing illustrates a dug region, and B of each drawing illustrates a planar region. In FIGS. 19A and 19B, the process is the same as that in the first embodiment until the SiN films 71 and 73 (see FIG. 14A) in the dug region is removed by wet etching to expose the fin-shaped semiconductor region 10. In the second embodiment, after the fin-shaped semiconductor region 10 is exposed, the manufacturing apparatus forms a resist pattern RP4 in the dug region and the planar region. The resist pattern RP4 has a shape to open partial regions including the trenches H11 and H12 and the vicinity thereof and cover the other regions.

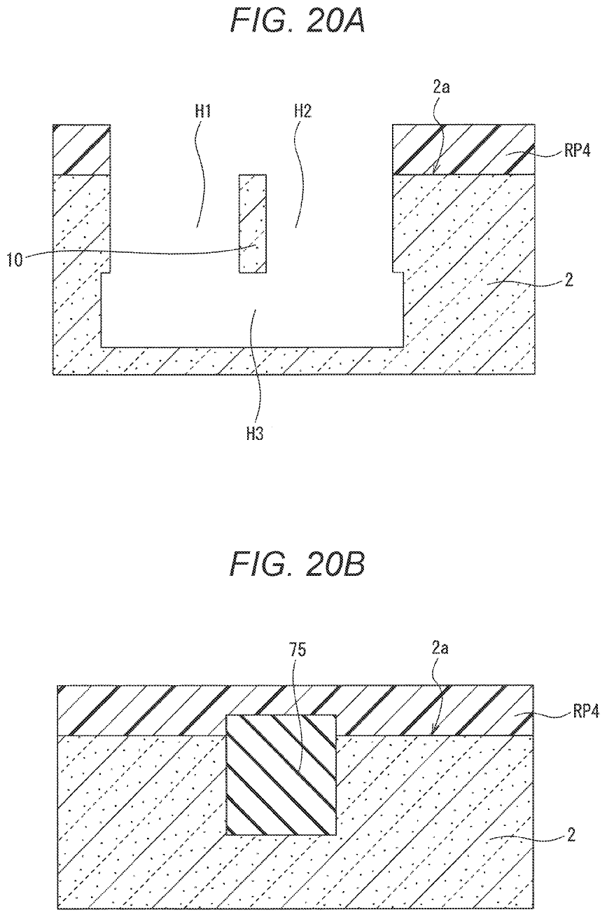

Next, the manufacturing apparatus etches and removes the SiO₂ films 74 and 75 in the dug region using the resist pattern RP4 as a mask. Therefore, as illustrated in FIGS. 20A and 20B, trenches H1 and H2 and a cavity H3 are formed in the dug region. The cavity H3 is formed in a region downward of the semiconductor region 10, and connects the trenches H1 and H2 to each other. The SiO₂ film 75 in the planar region remains unetched because it is covered with the resist pattern RP4. Thereafter, the manufacturing apparatus removes the resist pattern RP4.

Next, the manufacturing apparatus thermally oxidizes the semiconductor substrate 2 including the semiconductor region 10. Therefore, the manufacturing apparatus forms a gate insulating film 20 on the upper surface 10a, the first side surface 10b, the second side surface 10c, and the lower surface 10d of the semiconductor region 10 in the dug region, and forms a gate insulating film 20 on the front surface 2a of the semiconductor substrate 2 in the planar region.

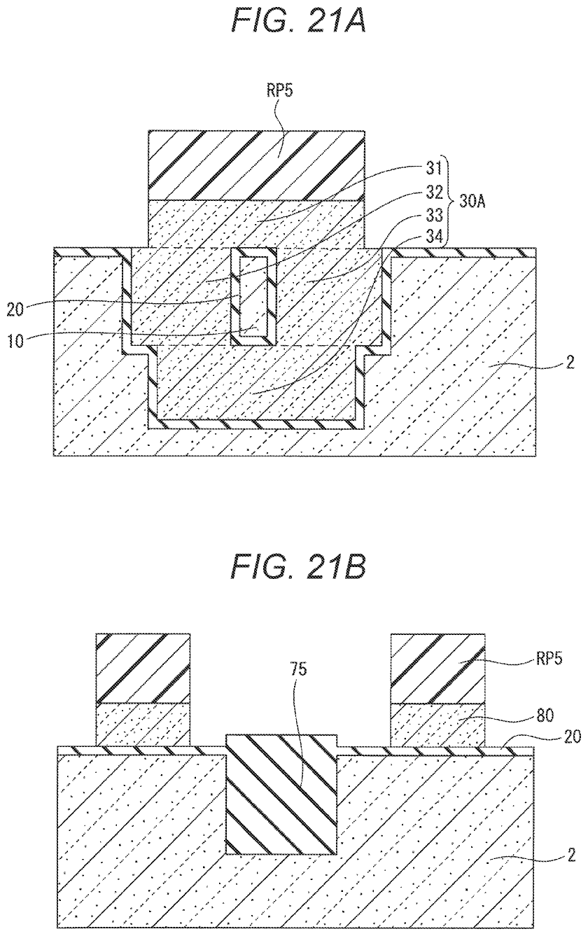

Next, the manufacturing apparatus forms a polysilicon film upward of the semiconductor substrate 2 to fill the trenches H1 and H2 and the cavity H3, using the CVD method. Next, as illustrated in FIGS. 21A and 21B, the manufacturing apparatus forms a resist pattern RP5 on the polysilicon film. The resist pattern RP5 has a shape to cover regions where gate electrodes are formed and open the other regions. Next, the manufacturing apparatus etches and removes the polysilicon film using the resist pattern RP5 as a mask. Therefore, a gate electrode 30A is formed in the dug region, and a gate electrode 80 is formed in the planar region. Thereafter, the manufacturing apparatus removes the resist pattern RP5. Thereafter, the manufacturing apparatus forms a source region and a drain region on the front surface 2a of the semiconductor substrate 2.

Through the above-described process, the semiconductor device 1A is completed with the MOS transistor 3A having the dug gate structure and the MOS transistor having the planar gate structure on the same semiconductor substrate 2.

As described above, the semiconductor device 1A according to the second embodiment of the present disclosure includes a semiconductor substrate 2 and a MOS transistor 3A in a dug gate structure provided on the semiconductor substrate 2. The MOS transistor 3A includes a semiconductor region 10 in which a channel is formed, a gate electrode 30A covering the semiconductor region 10, a gate insulating film 20 disposed between the semiconductor region 10 and the gate electrode 30A, and a first insulating film 51 disposed between the semiconductor region 10 and the semiconductor substrate 2. The semiconductor region 10 has a lower surface 10d located on the opposite side of the upper surface 10a. The gate electrode 30A has a fourth portion 34 facing the lower surface 10d with the gate insulating film 20 interposed therebetween, in addition to the first portion 31, the second portion 32, and the third portion 33.

As a result, the semiconductor device 1A has effects similar to those of the semiconductor device 1 according to the first embodiment. Furthermore, the gate electrode 30A can simultaneously apply a gate voltage to the semiconductor region 10 from a total of four directions including the upper and lower sides and the left and right sides. Therefore, the gate electrode 30A can completely deplete the semiconductor region 10 in an easier manner.

### Third Embodiment

The semiconductor device 1 according to the first embodiment or the semiconductor device 1A according to the second embodiment can be applied to an imaging device. Hereinafter, an example of the imaging device to which the semiconductor device 1 or 1A is applied will be described.

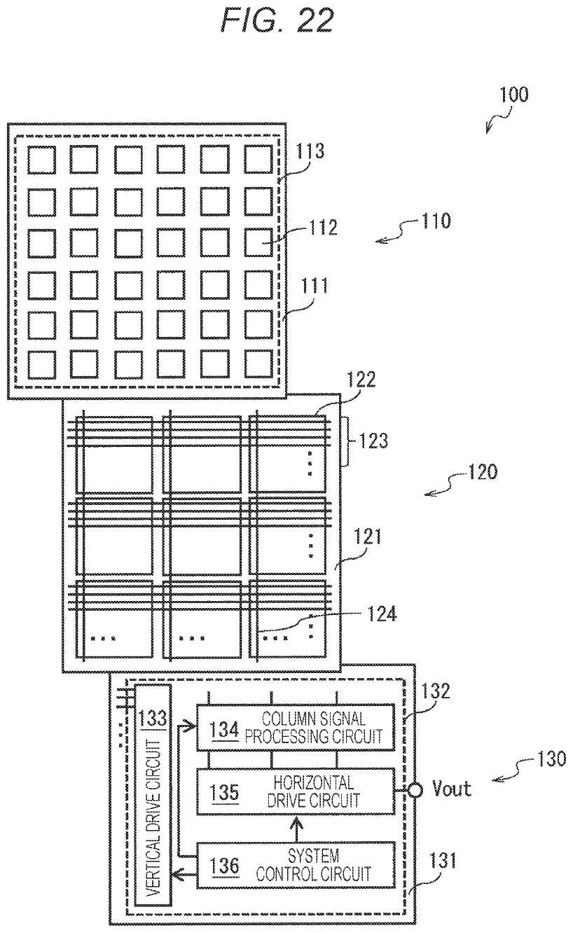

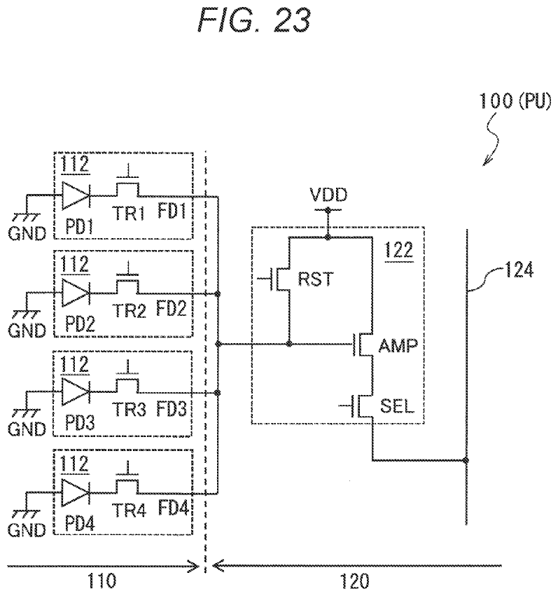

FIG. 22 is a schematic diagram illustrating a configuration example of an imaging device 100 according to a third embodiment of the present disclosure. The imaging device 100 includes a first substrate unit 110, a second substrate unit 120, and a third substrate unit 130. The imaging device 100 is an imaging device configured in a three-dimensional structure by bonding the first substrate unit 110, the second substrate unit 120, and the third substrate unit 130 to one another. The first substrate unit 110, the second substrate unit 120, and the third substrate unit 130 are stacked in this order.

The first substrate unit 110 includes a semiconductor substrate 111 and a plurality of sensor pixels 112 provided on the semiconductor substrate 111. The plurality of sensor pixels 112 performs photoelectric conversion. The plurality of sensor pixels 112 is provided in a matrix form in a pixel region 113 of the first substrate unit 110. The second substrate unit 120 includes a semiconductor substrate 121, a readout circuit 122 provided on the semiconductor substrate 121, a plurality of pixel drive lines 123 provided on the semiconductor substrate 121 and extending in a row direction, and a plurality of vertical signal lines 124 provided on the semiconductor substrate 121 and extending in a column direction. The readout circuit 122 outputs a pixel signal based on a charge output from the sensor pixel 112. One readout circuit 122 is provided for every four sensor pixels 112.

The third substrate unit 130 includes a semiconductor substrate 131 and a logic circuit 132 provided on the semiconductor substrate 131. The logic circuit 132 has a pixel signal processing function, and includes, for example, a vertical drive circuit 133, a column signal processing circuit 134, a horizontal drive circuit 135, and a system control circuit 136.

The vertical drive circuit 133, for example, sequentially selects the plurality of sensor pixels 112 on a row basis. The column signal processing circuit 134, for example, performs correlated double sampling (CDS) processing on a pixel signal output from each of the sensor pixels 112 in the row selected by the vertical drive circuit 133. For example, by performing the CDS processing, the column signal processing circuit 134 extracts a signal level of the pixel signal and holds pixel data corresponding to an amount of light received by each of the sensor pixels 112. The horizontal drive circuit 135, for example, sequentially outputs the pixel data held in the column signal processing circuit 134 to the outside. The system control circuit 136, for example, controls driving of each of the blocks (the vertical drive circuit 133, the column signal processing circuit 134, and the horizontal drive circuit 135) in the logic circuit 132.

FIG. 23 is a circuit diagram illustrating a configuration example of a pixel unit PU according to the third embodiment of the present disclosure. As illustrated in FIG. 23, in the imaging device 100, four sensor pixels 112 are electrically connected to one readout circuit 122 to constitute one pixel unit PU. The four sensor pixels 112 share one readout circuit 122, and an output from one of the four sensor pixels 112 is input to the shared readout circuit 122.

The sensor pixels 112 have identical components. In FIG. 23, identification numbers (1, 2, 3, and 4) are added to the ends of the signs (e.g., PD, TG, and FD to be described later) for the respective components of the sensor pixels 112 to distinguish the respective components of the sensor pixels 112 from each other. Hereinafter, in a case where it is not necessary to distinguish the respective components of the sensor pixels 112 from each other, the identification numbers at the ends of the signs for the respective components of the sensor pixels 112 will be omitted.

Each of the sensor pixels 112 includes, for example, a photodiode PD (an example of a “light receiving element” in the present disclosure), a transfer transistor TR electrically connected to the photodiode PD, and a floating diffusion FD temporarily holding a charge output from the photodiode PD via the transfer transistor TR. The photodiode PD performs photoelectric conversion to generate a charge corresponding to an amount of light received. A cathode of the photodiode PD is electrically connected to a source of the transfer transistor TR, and an anode of the photodiode PD is electrically connected to a reference potential line (e.g., the ground). A drain of the transfer transistor TR is electrically connected to the floating diffusion FD, and a gate electrode of the transfer transistor TR is electrically connected to the pixel drive line 123. The transfer transistor TR is, for example, a complementary metal oxide semiconductor (CMOS) transistor.

The respective floating diffusions FD of the sensor pixels 112 sharing one readout circuit 122 are electrically connected to each other, and are electrically connected to an input terminal of the common readout circuit 122. The readout circuit 122 includes, for example, an amplification transistor AMP, a reset transistor RST, and a selection transistor SEL. Note that the selection transistor SEL may be omitted if necessary.

A source of the reset transistor RST (the input terminal of the readout circuit 122) is electrically connected to the floating diffusions FD, and a drain of the reset transistor RST is electrically connected to a power supply line VDD and a drain of the amplification transistor AMP. A gate electrode of the reset transistor RST is electrically connected to the pixel drive line 123 (see FIG. 22). A source of the amplification transistor AMP is electrically connected to a drain of the selection transistor SEL, and a gate electrode of the amplification transistor AMP is electrically connected to the source of the reset transistor RST. A source of the selection transistor SEL (an output terminal of the readout circuit 122) is electrically connected to the vertical signal line 124, and a gate electrode of the selection transistor SEL is electrically connected to the pixel drive line 123 (see FIG. 22).

When the transfer transistor TR is turned on, the transfer transistor TR transfers a charge of the photodiode PD to the floating diffusion FD. The reset transistor RST resets a potential of the floating diffusion FD to a predetermined potential. When the reset transistor RST is turned on, the potential of the floating diffusion FD is reset to a potential of the power supply line VDD. The selection transistor SEL controls a timing at a pixel signal is output from the readout circuit 122.

The amplification transistor AMP generates a voltage signal corresponding to the level of the charge held in the floating diffusion FD as a pixel signal. The amplification transistor AMP constitutes a source follower type amplifier, and outputs a pixel signal having a voltage corresponding to the level of the charge generated in the photodiode PD. When the selection transistor SEL is turned on, the amplification transistor AMP amplifies the potential of the floating diffusion FD, and outputs a voltage corresponding to the potential to the column signal processing circuit 134 via the vertical signal line 124.

In the third embodiment of the present disclosure, the MOS transistor 3 described in the first embodiment or the MOS transistor 3A described in the second embodiment is used for one or more of the reset transistor RST, the amplification transistor AMP, the transfer transistor TR, and the selection transistor SEL.

For example, as illustrated in FIG. 23, the transfer transistor TR is provided on the first substrate unit 110. As the transfer transistor TR, the MOS transistor 3 or 3A having the dug gate structure may be used. In this case, the semiconductor substrate 111 corresponds to the semiconductor substrate 2 described in the first or second embodiment. Furthermore, the MOS transistor in the planar gate structure formed together with the MOS transistor 3 or 3A may be used for a pixel transistor other than the transfer transistor TR or a peripheral logic circuit disposed around the pixel region 113.

Furthermore, as illustrated in FIG. 23, the reset transistor RST, the amplification transistor AMP, and the selection transistor SEL are provided on the second substrate unit 120. The MOS transistor 3 or 3A having the dug gate structure may be used for one or more of the reset transistor RST, the amplification transistor AMP, and the selection transistor SEL. In this case, the semiconductor substrate 121 corresponds to the semiconductor substrate 2 described in the first or second embodiment. Furthermore, the MOS transistor in the planar gate structure formed together with the MOS transistor 3 or 3A may be used for a pixel transistor other than the reset transistor RST, the amplification transistor AMP, and the selection transistor SEL, or a peripheral logic circuit disposed around the readout circuit 122.

As described above, the imaging device 100 according to the third embodiment of the present disclosure includes a photodiode PD and a semiconductor device for transmitting an electric signal photoelectrically converted by the photodiode PD. The imaging device 100 includes the semiconductor device 1 (or the semiconductor device 1A) having a reduced substrate bias effect as at least a part of the semiconductor device for transmitting an electric signal. Therefore, the performance of the imaging device 100 can be improved, for example, by reducing noise of imaging data or the like.

### Other Embodiments

It should be understood that, although the present disclosure has been described with reference to the embodiments and the modifications above, the descriptions and the drawings constituting a part of this disclosure do not limit the present disclosure. From this disclosure, various alternative embodiments, examples, and application techniques will be apparent to those skilled in the art.

For example, a silicon oxynitride (SiON) film or a silicon nitride (Si₃N₄) film can also be used as the gate insulating film 20. Furthermore, a composite film formed by stacking several single-layer insulating films or the like can also be used as the gate insulating film 20. A MOSFET using an insulating film other than the SiO₂ film as the gate insulating film 20 may be referred to as a MISFET. The MISFET refers to a more generic field effect transistor including the MOSFET.

As described above, it is needless to say that the present technology includes various embodiments and the like that are not described herein. At least one of various omissions, substitutions, and alterations of the components may be made without departing from the gist of the embodiments and modifications described above. Furthermore, the effects described in the present specification are merely examples and are not limited, and there may be other effects as well.

Note that the present disclosure can also have the following configurations.

(1) A semiconductor device including:

a semiconductor substrate; and

a field effect transistor provided on a first main surface of the semiconductor substrate,

in which the field effect transistor includes a semiconductor region in which a channel is formed, a gate electrode covering the semiconductor region, a gate insulating film disposed between the semiconductor region and the gate electrode, and a first insulating film disposed between the semiconductor region and the semiconductor substrate,

the semiconductor region has an upper surface, a first side surface located on one side of the upper surface in a first direction parallel to the upper surface, and a second side surface located on the other side of the upper surface in the first direction, and

the gate electrode has a first portion facing the upper surface with the gate insulating film interposed therebetween, a second portion facing the first side surface with the gate insulating film interposed therebetween, and a third portion facing the second side surface with the gate insulating film interposed therebetween.

(2) The semiconductor device according to (1), in which a lower surface of the second portion and a lower surface of the third portion are located closer to the semiconductor substrate than a lower surface of the semiconductor region.

(3) The semiconductor device according to (1) or (2), further including:

a second insulating film disposed between the semiconductor substrate and the second portion; and

a third insulating film disposed between the semiconductor substrate and the third portion,

in which the second insulating film and the third insulating film are thinner than the first insulating film.

(4) The semiconductor device according to any one of (1) to (3), in which the semiconductor region has a lower surface located on an opposite side of the upper surface, and

the gate electrode has a fourth portion facing the lower surface with the gate insulating film interposed therebetween.

(5) The semiconductor device according to any one of (1) to (4), further including a source region and a drain region provided on the semiconductor substrate,

in which the source region is connected to one side of the semiconductor region in a second direction parallel to the upper surface and orthogonal to the first direction, and

the drain region is connected to the other side of the semiconductor region in the second direction.

(6) The semiconductor device according to (5), in which a length of the gate electrode in the second direction is 300 nm or more and 500 nm or less.

(7) The semiconductor device according to any one of (1) to (6), in which a length of the semiconductor region in a third direction orthogonal to the upper surface is 100 nm or more and 1000 nm or less.

(8) An imaging device including:

a light receiving element; and

a semiconductor device configured to transmit an electric signal photoelectrically converted by the light receiving element,

in which the semiconductor device includes a semiconductor substrate, and a field effect transistor provided on the semiconductor substrate,

the field effect transistor includes a semiconductor region in which a channel is formed, a gate electrode covering the semiconductor region, a gate insulating film disposed between the semiconductor region and the gate electrode, and a first insulating film disposed between the semiconductor region and the semiconductor substrate,

the semiconductor region has an upper surface, a first side surface located on one side of the upper surface in a first direction parallel to the upper surface, and a second side surface located on the other side of the upper surface in the first direction, and

the gate electrode has a first portion facing the upper surface with the gate insulating film interposed therebetween, a second portion facing the first side surface with the gate insulating film interposed therebetween, and a third portion facing the second side surface with the gate insulating film interposed therebetween.

### REFERENCE SIGNS LIST

1, 1A Semiconductor device
2 Semiconductor substrate
2a Front surface
2b Back surface
3, 3A MOS transistor
4 Element isolation layer
10 Semiconductor region
10a Upper surface
10b First side surface
10c Second side surface
10d, 32d, 33d Lower surface
20 Gate insulating film
30, 30A Gate electrode
31 First portion
32 Second portion
33 Third portion
34 Fourth portion
41 Source region
42 Drain region
51 First insulating film
52 Second insulating film
53 Third insulating film
71, 73 SiN film
73 SiN film
74, 75 SiO₂ film
80 Gate electrode
100 Imaging device
110 First substrate unit
111 Semiconductor substrate
112 Sensor pixel
113 Pixel region
120 Second substrate unit
121 Semiconductor substrate
122 Readout circuit
123 Pixel drive line
124 Vertical signal line
130 Third substrate unit
131 Semiconductor substrate
132 Logic circuit
133 Vertical drive circuit
134 Column signal processing circuit
135 Horizontal drive circuit
136 System control circuit
AMP Amplification transistor
FD Floating diffusion
H1, H2, H11, H12, H13 Trench
H2 Trench
PD Photodiode
PU Pixel unit
RP1, RP2, RP3, RP4, RP5 Resist pattern
RST Reset transistor
SEL Selection transistor
TR Transfer transistor
VDD Power supply line

1. A semiconductor device comprising:
a semiconductor substrate; and
a field effect transistor provided on a first main surface of the semiconductor substrate,
wherein the field effect transistor includes a semiconductor region in which a channel is formed, a gate electrode covering the semiconductor region, a gate insulating film disposed between the semiconductor region and the gate electrode, and a first insulating film disposed between the semiconductor region and the semiconductor substrate,
the semiconductor region has an upper surface, a first side surface located on one side of the upper surface in a first direction parallel to the upper surface, and a second side surface located on the other side of the upper surface in the first direction, and
the gate electrode has a first portion facing the upper surface with the gate insulating film interposed therebetween, a second portion facing the first side surface with the gate insulating film interposed therebetween, and a third portion facing the second side surface with the gate insulating film interposed therebetween.

2. The semiconductor device according to claim 1, wherein a lower surface of the second portion and a lower surface of the third portion are located closer to the semiconductor substrate than a lower surface of the semiconductor region.

3. The semiconductor device according to claim 1, further comprising:
a second insulating film disposed between the semiconductor substrate and the second portion; and
a third insulating film disposed between the semiconductor substrate and the third portion,
wherein the second insulating film and the third insulating film are thinner than the first insulating film.

4. The semiconductor device according to claim 1, wherein the semiconductor region has a lower surface located on an opposite side of the upper surface, and
the gate electrode has a fourth portion facing the lower surface with the gate insulating film interposed therebetween.

5. The semiconductor device according to claim 1, further comprising a source region and a drain region provided on the semiconductor substrate,
wherein the source region is connected to one side of the semiconductor region in a second direction parallel to the upper surface and orthogonal to the first direction, and
the drain region is connected to the other side of the semiconductor region in the second direction.

6. The semiconductor device according to claim 5, wherein a length of the gate electrode in the second direction is 300 nm or more and 500 nm or less.

7. The semiconductor device according to claim 1, wherein a length of the semiconductor region in a third direction orthogonal to the upper surface is 100 nm or more and 1000 nm or less.

8. An imaging device comprising:
a light receiving element; and
a semiconductor device configured to transmit an electric signal photoelectrically converted by the light receiving element,
wherein the semiconductor device includes a semiconductor substrate, and a field effect transistor provided on the semiconductor substrate,
the field effect transistor includes a semiconductor region in which a channel is formed, a gate electrode covering the semiconductor region, a gate insulating film disposed between the semiconductor region and the gate electrode, and a first insulating film disposed between the semiconductor region and the semiconductor substrate,
the semiconductor region has an upper surface, a first side surface located on one side of the upper surface in a first direction parallel to the upper surface, and a second side surface located on the other side of the upper surface in the first direction, and
the gate electrode has a first portion facing the upper surface with the gate insulating film interposed therebetween, a second portion facing the first side surface with the gate insulating film interposed therebetween, and a third portion facing the second side surface with the gate insulating film interposed therebetween.
